(19) United States
(12) Patent Application Publication
(10) Pub. No.: US 2024/0014332 A1
(43) Pub. Date: Jan. 11, 2024

(54) METHOD FOR MAKING AN ELECTRODE OF A PHOTOVOLTAIC CELL

(71) Applicant: SUZHOU SUNWELL NEW ENERGY CO., LTD., Suzhou (CN)

(72) Inventors: Yu Yao, Suzhou (CN); Zhongtian Li, Suzhou (CN)

(21) Appl. No.: 18/460,366

(22) Filed: Sep. 1, 2023

Related U.S. Application Data
(63) Continuation-in-part of application No. PCT/CN2022/078531, filed on Mar. 1, 2022.

(30) Foreign Application Priority Data
Mar. 2, 2021 (CN) 202110229573.1

(51) Int. Cl. H01L 31/0224; C25D 5/02; C23C 18/16

(52) U.S. Cl. CPC H01L 31/022425; C25D 5/022; C23C 18/1608

(57) ABSTRACT

Provided is a method for making an electrode of a photovoltaic cell. The method includes the following steps: a mask material is deposited over the side and at least one surface of a photovoltaic device, where the mask material layer is divided into body part and opening part; the opening part is patterned to form a local opening; metal is electrochemically deposited in the local opening to form an electrode; and the body part is removed.

### CROSS-REFERENCE TO RELATED APPLICATION(S)

The present application is a continuation-in-part of International Patent Application Serial No. PCT/CN2022/078531, filed Mar. 1, 2022, which claims priority to Chinese Patent Application Serial No. CN 202110229573.1, filed Mar. 2, 2021, which are incorporated herein by reference in their entireties.

### TECHNICAL FIELD

The present application relates to the field of photovoltaic cells and semiconductor fabrication, for example, a method for making an electrode of a photovoltaic cell.

### BACKGROUND

As the structure of crystalline-silicon photovoltaic cells is being developed to have higher open-circuit voltage, low-temperature processes in a manufacturing process of the photovoltaic cells have been increasingly applied to keep bulk and surface passivation intact. A silicon heterojunction cell is used as an example. Materials deposited at low temperature on a silicon substrate include an intrinsic amorphous silicon layer, a doped amorphous silicon layer, and a transparent conductive layer such as indium tin oxide. The amorphous silicon layer is generally deposited by plasma-enhanced chemical vapor deposition (PECVD) and the transparent conductive layer is generally deposited by physical vapor deposition such as magnetron sputtering or reactive plasma deposition. However, in the deposition of a substance transitioning from the gas phase to the solid phase, material deposition inevitably occurs on the sides of a photovoltaic cell with wrap-around effect. For a double sided solar cell, the light-receiving surface and the backside exhibit opposite polarity, therefore it is essential to form an insulation region on the side or the edge of a certain surface to prevent localized shunts or short-circuit of the two surfaces.

When screen printing is used for depositing metal on the surface of the photovoltaic cell, the risk of an edge short circuit is greatly reduced because the pattern of the screen can limit the metal so that the metal only contacts the surface of one certain polarity. However, due to the height and width limitations of grid lines formed by the screen printing and high dependence on silver paste, more efficient photovoltaic cells increasingly use electroplated copper as a main conductive material.

During the electroplating process, when a solution containing copper ions contacts the conductive surface of a photovoltaic cell (including the side of the photovoltaic cell), copper metal is deposited on the side of the photovoltaic cell, and the deposited copper metal is typically removed by post-etching on the side of the photovoltaic cell, thereby reducing edge short circuits. Post-etching requires adding a surface protection layer on other surfaces (not the side) of the photovoltaic cell, resulting in an increased manufacturing cost. Moreover, the post-etching damages the surface of the photovoltaic cell, affecting the efficiency and yield of the photovoltaic cell.

### SUMMARY

Embodiments of the present application provide a method for making an electrode of a photovoltaic cell.

The method for making an electrode of a photovoltaic cell includes S1, S2, S3, and S4.

In S1, a mask material is deposited over a side and at least one surface of a photovoltaic device to form a mask material layer over the side and the at least one surface, where the mask material layer is divided into body part and opening part.

In S2, a patterning process is performed on the opening part to form a local opening.

In S3, metal is electrochemically deposited in the local opening to form an electrode by using an electrochemical deposition method.

In S4, the body part is removed.

### BRIEF DESCRIPTION OF DRAWINGS

FIGS. 1A to 1F are schematic flowcharts of a method for making an electrode according to an embodiment of the present application.

FIGS. 2A to 2F are schematic flowcharts of a method for making an electrode according to another embodiment of the present application.

FIGS. 3A to 3E are schematic flowcharts of a method for making an electrode according to another embodiment of the present application.

FIGS. 4A to 4C are schematic flowcharts of a method for making an electrode according to another embodiment of the present application.

FIGS. 5A to 5C are schematic flowcharts of the process in which a mask material layer is formed according to another embodiment of the present application.

FIGS. 6A to 6C are schematic flowcharts of the process in which a mask material layer is formed according to another embodiment of the present application.

FIGS. 7A to 7C are schematic flowcharts of the process in which a mask material layer is formed according to another embodiment of the present application.

FIG. 8 is a diagram of the layout of a printing head according to another embodiment of the present application.

FIG. 9 is a diagram of the distribution of local openings on one surface of a photovoltaic device according to another embodiment of the present application.

FIGS. 10A to 10C are schematic flowcharts of the process in which a mask material layer is formed according to another embodiment of the present application.

FIGS. 11A to 11D are schematic flowcharts of a method for making an electrode according to another embodiment of the present application.

### DETAILED DESCRIPTION

Technical solutions in embodiments of the present invention are described further below in conjunction with accompanying drawings and specific embodiments. The following embodiments are only used to illustrate the technical solutions in embodiments of the present invention more clearly.

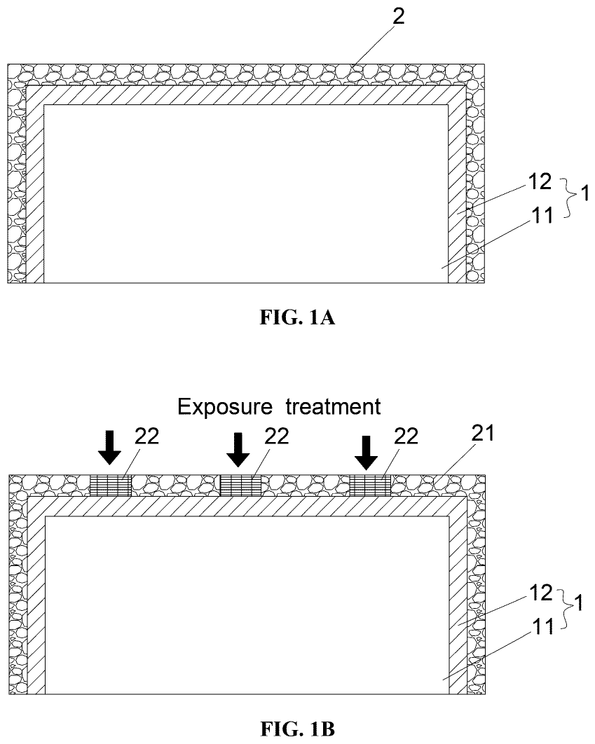

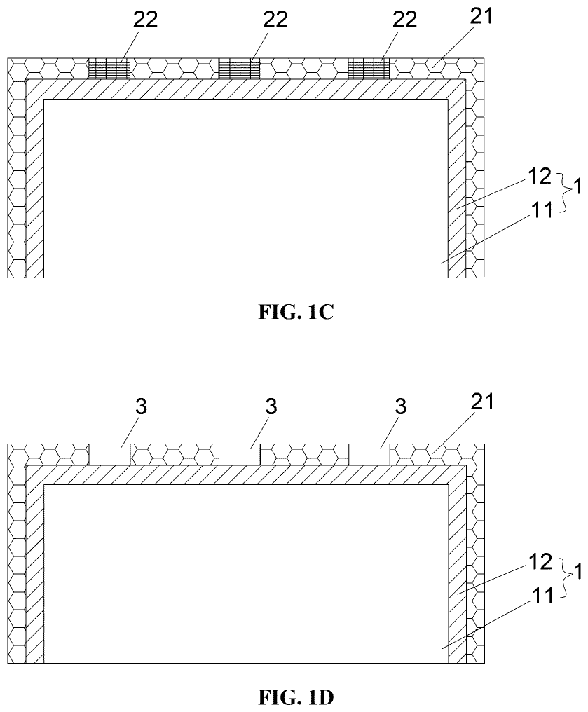

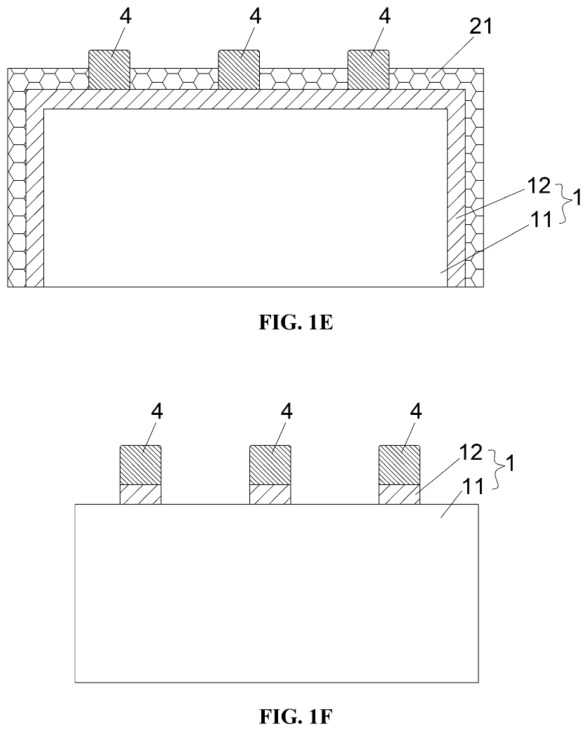

As shown in FIGS. 1A to 1F, embodiments of the present application provide a method for making an electrode of a photovoltaic cell. The method includes the following steps:

A mask material is deposited over a side and at least one surface of a photovoltaic device 1 so that a mask material layer 2 is formed over the side and the surface, as shown in FIG. 1A. The surface herein refers to the upper surface and/or the lower surface of the photovoltaic device 1 in the direction of thickness. The side refers to the side extending in the direction of the thickness of the photovoltaic device 1. The number of the side is generally four. The photovoltaic device 1 may be a photovoltaic cell during production. A deposition method of the mask material may be one or a combination of two or more of screen printing, roller coating, brush coating, slit coating, curtain coating, spray coating, spin coating, or inkjet printing. The mask material may be deposited over the side and the surface of the photovoltaic device 1 simultaneously by one-step deposition. Alternatively, the mask material may be deposited over the side and the surface of the photovoltaic device 1 separately.

In this embodiment, the photovoltaic device 1 includes a device body 11 and a conductive seed layer 12 covering the surface and side of the device body 11, and the mask material over the surface and side of the photovoltaic device 1 is deposited over the surface of the conductive seed layer 12, as shown in FIG. 1A. The conductive seed layer 12 may be a single layer structure or a multi-layer structure, and the material of each layer of the conductive seed layer 12 includes any one or an alloy of two or more of nickel, copper, or tin. The mask material may be a wet film photoresist, a dry film photoresist, or a photosensitive ink. Optionally, the mask material may include a phenolic resin.

As shown in FIG. 1B, ultraviolet light or laser (for example laser direct writing) is used for locally exposing the mask material layer 2 so that a photopolymerization reaction, a photocross-linking reaction, or a photodecomposition reaction occurs on an exposed region. The wavelength range of the ultraviolet light or the laser is 300 nm to 450 nm, for example, 350 nm to 420 nm; and the wavelength range is exemplarily 365 nm to 405 nm. The mask material layer 2 over the side and the surface is divided into a body part 21 and opening part 22 according to whether an opening is required in a corresponding region, that is, according to whether an electrode 4 is needed to be formed later in the corresponding region. All the opening parts 22 are formed on the surface of the photovoltaic device 1. In this embodiment, the body part 21 does not need to be exposed, and the opening part 22 needs to be exposed by, for example, the preceding ultraviolet light or laser direct writing.

As shown in FIG. 1C, the body part 21 that is not exposed on the surface and the side is subsequently subjected to resist and anti-plating treatment. The resist treatment and anti-plating treatment include using heat treatment to cause a photopolymerization reaction or a photocross-linking reaction on the body part 21 to form a reacted mask material layer 2.

A developer is used to remove the opening part 22 to form the local opening 3, so that the conductive seed layer 12 on the surface of the photovoltaic device 1 is exposed in the local opening 3, as shown in FIG. 1D. The number of the opening part 22 may be one or more, and the number of the local opening 3 may be one or more. The developer may be tetramethylammonium hydroxide solution or sodium carbonate solution.

An electrode 4 is formed by electrochemical deposition of metal in the local opening 3, as shown in FIG. 1E. The electrochemically depositing method may be electroplating deposition adopted or may be chemical deposition in this embodiment. The electrode 4 may be a single layer structure or a multi-layer structure, and the material of each layer of the electrode 4 includes any one or an alloy of two or more of nickel, copper, tin, silver, bismuth, or indium.

The body part 21, reacted mask material layer 2 over the surface and the side of the photovoltaic device 1, is finally removed, and the conductive seed layer 12 except the part occupied by the electrode 4 is removed, as shown in FIG. 1F. In this embodiment, the electrode 4 over the photovoltaic device 1 is finished.

It should be understood that the resist and anti-plating treatment shown in FIG. 1C is an optional operation, and that in the method for making an electrode according to this embodiment, a developer is used to remove opening part 22 after exposing the opening part 22 by ultraviolet light or laser to form the local opening 3, so that the conductive seed layer 12 on the surface of the photovoltaic device 1 is exposed in the local opening 3. Alternatively, the resist and anti-plating treatment shown in FIG. 1C may also be performed after local opening 3 is formed. For example, after local opening 3 is formed, the body part 21 is subjected to resist and anti-plating treatment. Then metal is electrochemically deposited in local opening 3 to form an electrode 4. The resist treatment and anti-plating treatment include using light or heat treatment to cause a photopolymerization reaction or a photocross-linking reaction on the body part 21 to form a reacted mask material layer 2.

Additionally, it should be understood that the preceding resist and anti-plating treatment may be performed on the body part 21 or only on the mask material layer over the side.

If the resist and anti-plating treatment is not performed on the side of the photovoltaic device 1, or the side of the photovoltaic device 1 is not covered by the mask material layer, it may cause the metal that should be electrochemically deposited on the surface to be deposited on the conductive layer on the side. As a result, the light-facing surface (usually positive or negative) and the backlight surface (usually negative or positive) of the photovoltaic device 1 may be completely or locally short-circuited on the side, which affects the photoelectric conversion efficiency of the photovoltaic device 1, especially the photoelectric conversion efficiency under a low-light condition. The conventional treatment method for the side is as follows: The side is not protected first, and after metallization, the metal deposited on the side is etched away, thereby reducing the risk of short circuits on the side. In this embodiment, the mask material with a certain viscosity is deposited on the surface and the side of the photovoltaic device 1 by an appropriate manner so that the risk of an edge short circuit of the photovoltaic device 1 caused by metal deposition on the side during the process of making the electrode 4 may be prevented.

When the mask material is deposited over the side and the surface of the photovoltaic device 1 separately, an overlapping region exists between the mask material layer 2 over the side and the mask material layer 2 over the surface. In this manner, a gap is prevented between the mask material layer 2 over the side and the mask material layer 2 over the surface, thereby preventing depositing metal on the gap in subsequent plating.

For example, the mask material layer 2 is formed over the upper surface and/or the lower surface by screen printing, and the mask material layer 2 is formed over the side by roller coating. The photovoltaic device 1 has a sheet-like structure. The upper surface of the photovoltaic device 1 is a flat surface of a relatively large area, and screen printing can print the mask material layer 2 over the flat surface of a relatively large area. Similarly, the lower surface of the photovoltaic device 1 is a flat surface of a relatively large area, and screen printing can print the mask material layer 2 over the flat surface of a relatively large area. The side is relatively narrow, and it is inconvenient to form the mask material layer 2 by using screen printing. Roller coating may be used to coat in the extension direction of the side to form the mask material layer 2. The side of the photovoltaic device 1 includes multiple continuous surfaces, so the mask material layer 2 can be formed over the multiple continuous surfaces by continuously roller coating.

When the mask material is deposited over the side and the surface of the photovoltaic device 1 simultaneously by one-step deposition, the mask material layer 2 over the side and the surface is integrally formed so that a joint is not formed at the junction of the side and the surface, thereby reducing the risk of depositing metal over the side in subsequent plating. Additionally, the mask material is deposited over the side and the surface of the photovoltaic device 1 simultaneously by one-step deposition, requiring no additional side coating equipment and processes, which is fully compatible with subsequent patterning and de-masking. Therefore, no additional special treatment for the side is required. The amount of mask material in the manner where the mask material is simultaneously deposited over the side and over the surface in one step is less than the amount of mask material in the manner where the mask material is deposited over the side and over the surface separately so that the material, technique, and equipment cost are reduced.

Embodiments of the present application also provide a photovoltaic cell. The photovoltaic cell includes the electrode 4 made by the preceding method.

Embodiments of the present application also provide a method for making photovoltaic cell. The method for making photovoltaic cell includes preceding method for making an electrode.

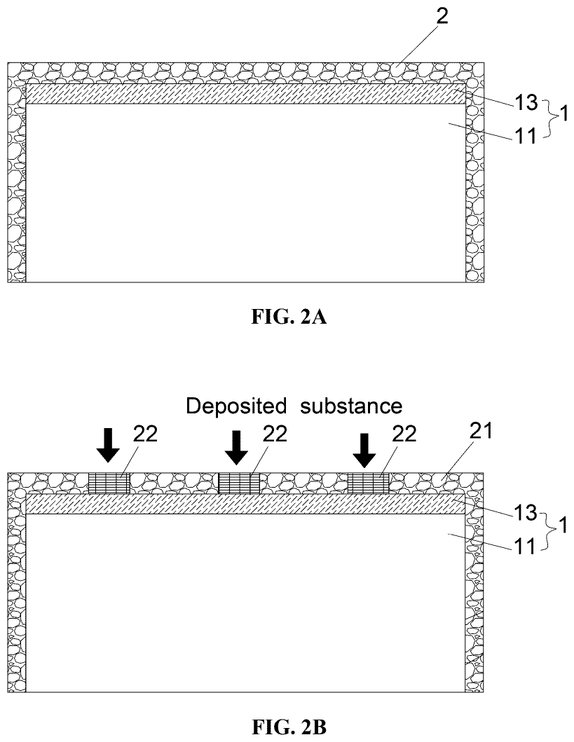

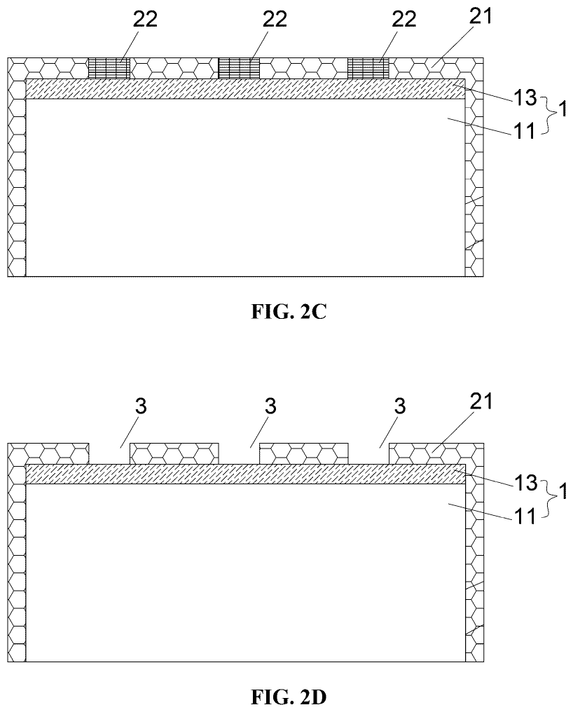

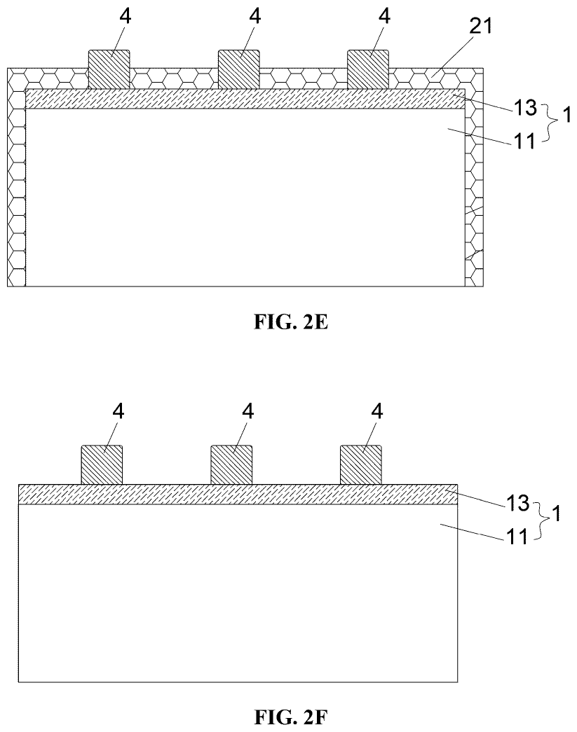

As shown in FIGS. 2A to 2F, another embodiment of the present application provides a method for making an electrode of a photovoltaic cell. The method includes the following steps:

A mask material is deposited over a side and at least one surface of a photovoltaic device 1 to form a mask material layer 2 over the side and the surface, as shown in FIG. 2A. The surface herein refers to the upper surface and/or the lower surface of the photovoltaic device 1 in the direction of thickness. A deposition method of the mask material may be one or a combination of two or more of screen printing, roller coating, brush coating, slit coating, curtain coating, spray coating, spin coating, or inkjet printing. The mask material may be deposited over the side and the surface of the photovoltaic device 1 simultaneously by one-step deposition. Alternatively, the mask material may be deposited over the side and the surface of the photovoltaic device 1 separately.

In this embodiment, the photovoltaic device 1 includes a device body 11 and a conductive layer 13 covering the surface of the device body 11; the mask material over the surface of the photovoltaic device 1 is deposited over the surface of the conductive layer 13; the mask material over the side of the photovoltaic device 1 is deposited over the side of the device body 11 and the conductive layer 13, as shown in FIG. 2A. The conductive material of the preceding conductive layer 13 is one or a mixed material of two or more conductive materials of doped polysilicon, doped amorphous silicon, doped silicon carbide, transparent conductive oxide, or a conductive seed layer; or the conductive material is formed by two or more the preceding conductive materials being stacked in the direction of thickness.

For the mask material formed over the surface, a substance reacting with the mask material is locally deposited. The preceding local deposition may be achieved by means such as inkjet printing. The mask material layer 2 over the side and the surface is divided into a body part 21 and opening part 22 according to whether an opening is required in a corresponding region, that is, according to whether an electrode 4 is needed to be formed later in the corresponding region. The opening part 22 is formed on the surface of the photovoltaic device 1. In this embodiment, no substance needs to be deposited in the body part 21, and a substance needs to be deposited on the opening part 22 so that the mask material of the opening part 22 reacts with the deposited substance, as shown in FIG. 2B.

Heat treatment or chemical treatment is subsequently performed on the body part 21 on the surface and the side where no substance is deposited so as to cause a photopolymerization reaction, a photocross-linking reaction, or a photodecomposition reaction to form a reacted mask material layer 2, as shown in FIG. 2C.

A developer is used to act on the opening part 22 having reacted with the deposited substance so that the opening part 22 is removed to form local opening 3. In this manner, the conductive layer 13 on the surface of the photovoltaic device 1 is exposed in the local opening 3, as shown in FIG. 2D.

An electrode 4 is formed by electrochemical deposition of metal in the local opening 3, as shown in FIG. 2E. Electrochemically depositing metal may be electroplating deposition adopted in this embodiment or may be chemical deposition. The electrode 4 may be a single layer structure or a multi-layer structure, and the material of each layer of the electrode 4 includes any one or an alloy of two or more of nickel, copper, tin, silver, bismuth, or indium.

The body part 21, reacted mask material layer 2 over the surface and the side of the photovoltaic device 1, is finally removed, as shown in FIG. 2F. The reacted mask material layer 2 over the surface and the side may be removed in one step or step by step. In this embodiment, the electrode 4 over the photovoltaic device 1 is finished.

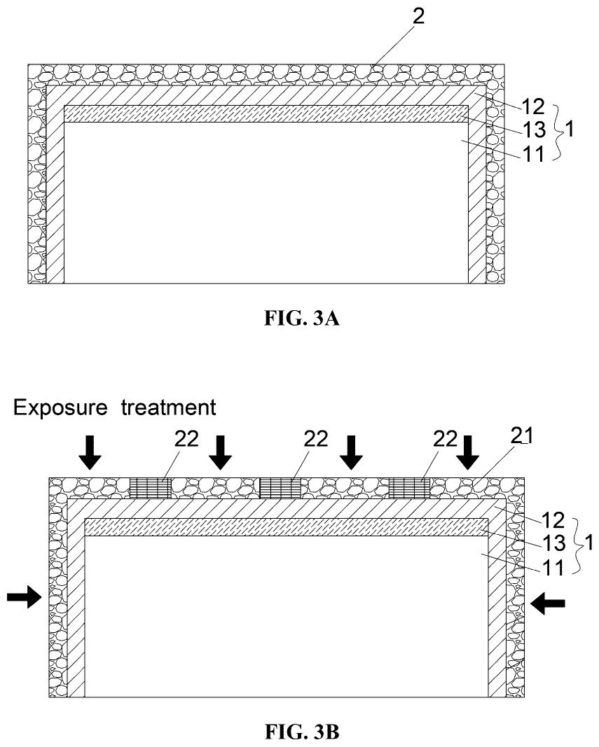

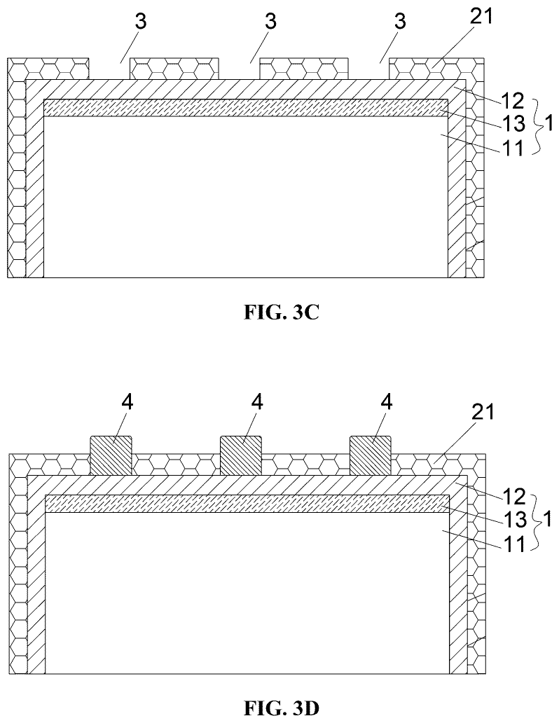

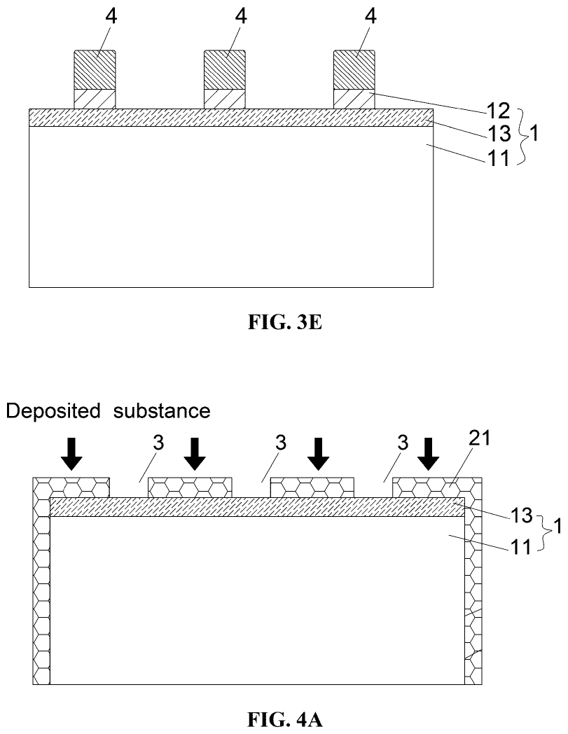

As shown in FIGS. 3A to 3E, another embodiment of the present application provides a method for making an electrode of a photovoltaic cell. The method includes the following steps:

A mask material is deposited over a side and at least one surface of a photovoltaic device 1; a mask material layer 2 is formed over the side and the surface, as shown in FIG. 3A. The surface herein refers to the upper surface and/or the lower surface of the photovoltaic device 1 in the direction of thickness. A deposition method of the mask material may be one or a combination of two or more of screen printing, roller coating, brush coating, slit coating, curtain coating, spray coating, spin coating, or inkjet printing. The mask material may be deposited over the side and the surface of the photovoltaic device 1 simultaneously by one-step deposition. Alternatively, the mask material may be deposited over the side and the surface of the photovoltaic device 1 separately.

In this embodiment, the photovoltaic device 1 includes a device body 11, a conductive layer 13 covering the surface of the device body 11, and a conductive seed layer 12 covering the surface of the conductive layer 13 and the side of the device body 11, and the mask material over the surface and side of the photovoltaic device 1 is deposited over the surface of the conductive seed layer 12, as shown in FIG. 3A.

The mask material layer 2 over the side and the surface is divided into a body part 21 and opening part 22 according to whether an opening is required in a corresponding region, that is, according to whether an electrode 4 is needed to be formed later in a corresponding region. Ultraviolet light or laser is used to act on the mask material layer of the body part 21 on the surface and the side so that a photocross-linking reaction or a photopolymerization reaction occurs on the mask material of the body part 21 to form a reacted mask material layer 2 while the mask material of the opening part 22 is not acted on by the ultraviolet light or laser, as shown in FIG. 3B. The wavelength range of the preceding ultraviolet light or the laser is 300 nm to 450 nm; preferably, 350 nm to 420 nm; and more preferably, 365 nm to 405 nm.

Subsequently, a developer is used to remove the opening part 22 to form the local opening 3, so that the conductive seed layer 12 on the surface of the photovoltaic device 1 is exposed in the local opening 3, as shown in FIG. 3C.

An electrode 4 is formed by electrochemical deposition of metal in local opening 3, as shown in FIG. 3D. Electrochemically depositing metal may be electroplating deposition adopted in this embodiment or may be chemical deposition. The electrode 4 may be a single layer structure or a multi-layer structure, and the material of each layer of the electrode 4 includes any one or an alloy of two or more of nickel, copper, tin, silver, bismuth, or indium.

The body part 21, reacted mask material layer 2 over the surface and the side of the photovoltaic device 1, is removed, and the conductive seed layer 12 except the part occupied by the electrode 4 is removed, as shown in FIG. 3E. In this embodiment, the electrode 4 over the photovoltaic device 1 is finished.

Embodiments of the present application also provide a photovoltaic cell. The photovoltaic cell includes the electrode 4 made by the preceding method.

Embodiments of the present application also provide a method for making photovoltaic cell. The method for making photovoltaic cell includes preceding method for making an electrode.

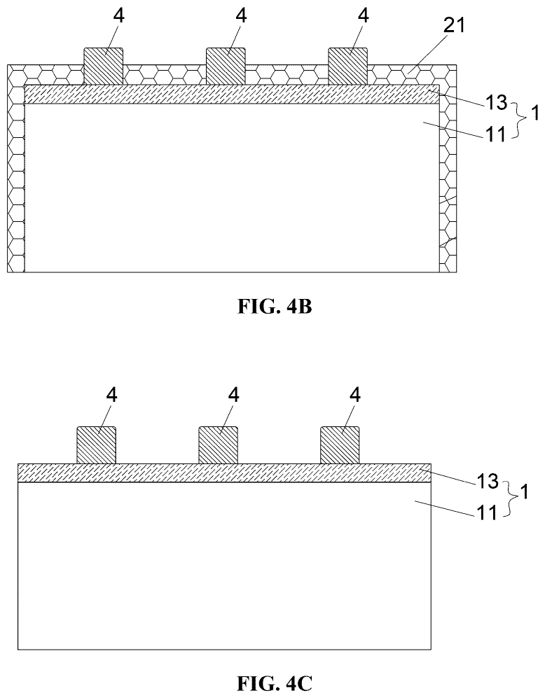

As shown in FIGS. 4A to 4C, another embodiment of the present application provides a method for making an electrode of a photovoltaic cell. The method includes the following steps:

A mask material is deposited over a side and at least one surface of a photovoltaic device 1 by inkjet printing. The surface herein refers to the upper surface and/or the lower surface of the photovoltaic device 1 in the direction of thickness. For the mask material formed over the surface, the mask material is printed, by inkjet printing, on a region where metal does not need to be deposited so as to directly form a mask material layer 2 with local opening 3. In other words, a mask material layer 2 having only the body part 21 is directly deposited and formed over the surface and the side of the photovoltaic device 1, as shown in FIG. 4A.

In this embodiment, the photovoltaic device 1 includes a device body 11 and a conductive layer 13 covering the surface of the device body 11; the mask material over the surface of the photovoltaic device 1 is deposited over the surface of the conductive layer 13; the mask material over the side of the photovoltaic device 1 is deposited over the side of the device body 11 and conductive layer 13, as shown in FIG. 4A. The conductive material of the preceding conductive layer 13 is one or a mixed material of two or more conductive materials of doped polysilicon, doped amorphous silicon, doped silicon carbide, transparent conductive oxide, or a conductive seed layer, or the conductive material is formed by two or more conductive materials being stacked in the direction of thickness.

Metal is electroplated and deposited in the local opening 3 to form an electrode 4. The electrode 4 may be a single layer structure or a multi-layer structure, and the material of each layer of the electrode 4 includes any one or an alloy of two or more of nickel, copper, tin, silver, bismuth, or indium, as shown in FIG. 4B.

The body part 21, mask material layer 2 over the surface and the side of the photovoltaic device 1, is finally removed, as shown in FIG. 4C.

Embodiments of the present application also provide a photovoltaic cell. The photovoltaic cell includes the electrode 4 made by the preceding method.

Embodiments of the present application also provide a method for making photovoltaic cell. The method for making photovoltaic cell includes preceding method for making an electrode.

Another embodiment of the present application provides a method for making an electrode of a photovoltaic cell. The method includes the following steps:

A mask material is deposited over a side and at least one surface of a photovoltaic device 1; a mask material layer 2 is formed over the side and the surface. For example, a mask material is deposited over the side and at least one surface of a photovoltaic device 1, and a mask material layer 2 is formed over the side and the surface, where this process may refer to the schematic diagram shown in FIG. 1A. The surface herein refers to the upper surface and/or the lower surface of the photovoltaic device 1 in the direction of thickness. A deposition method of the mask material may be one or a combination of two or more of screen printing, roller coating, brush coating, slit coating, curtain coating, spray coating, spin coating, or inkjet printing. The mask material may be deposited over the side and the surface of the photovoltaic device 1 simultaneously by one-step deposition. Alternatively, the mask material may be deposited over the side and the surface of the photovoltaic device 1 separately. For example, the mask material layer 2 over the side and the surface is divided into a body part 21 and opening part 22 according to whether an opening is required in a corresponding region, that is, according to whether an electrode 4 is needed to be formed later in a corresponding region. The opening part 22 is formed on the surface of the photovoltaic device 1.

The mask material layer 2 over the surface is patterned to form a local opening 3. For example, ultraviolet light or laser direct writing is used for exposing the opening part 22 so that a photopolymerization reaction, a photocross-linking reaction, or a photodecomposition reaction occurs on the opening part 22; a developer is used to remove the opening part 22 to form the local opening 3, so that the conductive seed layer 12 on the surface of the photovoltaic device 1 is exposed in the local opening 3, where this process may refer to the schematic diagram shown in FIGS. 1B and 1C.

The wavelength range of the ultraviolet light or the laser is 300 nm to 450 nm, for example, 350 nm to 420 nm; and the wavelength range is exemplarily 365 nm to 405 nm.

When the mask material is a positive resist, the body part 21 does not need to be exposed, and the opening part 22 needs to be exposed by, for example, the preceding ultraviolet light or laser direct writing. Reference may be made to the schematic diagram shown in FIG. 1B. When the mask material is a negative resist, the opening part 22 does not need to be exposed, and the body part 21 needs to be exposed by, for example, the preceding ultraviolet light or laser direct writing.

When the mask material is a positive resist, the body part 21 or the mask material layer 2 over the side is subjected to resist and anti-plating treatment after the opening part 21 is exposed by ultraviolet light or laser (which may be referred to as a first exposure treatment). For example, the resist treatment and anti-plating treatment include using heat treatment to cause a photopolymerization reaction or a photocross-linking reaction on the mask material of the body part 21 to form a reacted mask material layer 2, as shown in FIG. 1C. Afterwards, a developer is used to remove the opening part 22 (which may be referred to as a development treatment). Alternatively, after the opening part 22 is exposed by ultraviolet light or laser, a developer is used to remove the opening part 22, and then the body part 21 or the mask material layer 2 over the side is subjected to resist and anti-plating treatment. For example, the resist treatment and anti-plating treatment include using light or heat treatment to cause a photopolymerization reaction or a photocross-linking reaction on the mask material of the body part 21 to form a reacted mask material layer 2. After that, an electrode 4 is formed by electrochemical deposition of metal in each local opening 3 (which may be referred to as an electroplating treatment).

That is to say, when the mask material is a positive resist, if the body part 21 or the mask material layer 2 over the side is subjected to resist and anti-plating treatment, two treatment methods exist, namely, light treatment and heat treatment. The heat treatment may be performed after the first exposure treatment and before the development treatment or the heat treatment may be performed after the development treatment and before the electroplating treatment. The light treatment is performed after the development treatment and before the electroplating treatment.

When the mask material is a negative resist, the body part 21 or the mask material layer 2 over the side undergoes the first exposure treatment before development, and after development and before electroplating, the mask material layer 2 over the side may be subjected to light treatment again (which may be referred to as a second exposure treatment). The second exposure treatment is to subject the body part 21 or the mask material layer 2 over the side to resist and anti-plating treatment so as to cause a photopolymerization reaction or a photocross-linking reaction on the mask material of the body part 21 and/or over the side. In this manner, a reacted mask material layer 2 is obtained. The second exposure treatment may be merged into the process of the first exposure treatment, that is, in the first exposure treatment before development, the exposure energy (exposure time and/or exposure power) act on the body part 21 or the mask material layer 2 over the side is increased, so as to achieve the effect of resist and anti-plating. It should be understood that after the development treatment and before the electroplating treatment, heat treatment, besides light treatment, may also be used to subject the body part 21 or the mask material layer 2 over the side to resist and anti-plating treatment. Alternatively, after the first exposure treatment and before the development treatment, heat treatment is used to subject the body part 21 or the mask material layer 2 over the side to resist and anti-plating treatment.

That is to say, when the mask material is a negative resist, if the body part 21 or the mask material layer 2 over the side is subjected to resist and anti-plating treatment, two treatment methods exist, namely, light treatment and heat treatment. Either the light treatment or heat treatment may be performed after the first exposure treatment and before the development treatment or may be performed after the development treatment and before the electroplating treatment.

The preceding electrochemical deposition of metal in the local opening 3 to form an electrode 4 may include electroplating deposition or chemical deposition. The electrode 4 may be a single layer structure or a multi-layer structure, and the material of each layer of the electrode 4 includes any one or an alloy of two or more of nickel, copper, tin, silver, bismuth, or indium.

Optionally, when the local opening 3 is formed only on the upper surface or the lower surface of the photovoltaic device 1, metal is electrochemically deposited in the local opening 3 to form an electrode 4, and correspondingly, a single-sided photovoltaic cell is finished. When the local opening 3 is formed on the upper surface and the lower surface of the photovoltaic device 1, metal is electrochemically deposited in the local opening 3 to form an electrode 4, and correspondingly, a double-sided photovoltaic cell is finished.

Multiple local openings 3 on the same surface of the photovoltaic device 1 are provided. The electrode 4 may be formed by electrochemically depositing metal in part of the multiple local openings 3, and another electrode 4 may be formed by electrochemically depositing metal in another part of the multiple local openings 3.

The mask material layer 2 over the surface and the side of the photovoltaic device 1 is removed.

For example, chemical liquid may be used to remove the mask material layer 2 over the surface and the side of the photovoltaic device 1, where the mask material layer 2 over the side is first dissolved and removed, and then the mask material layer 2 over the surface, after being swollen, is peeled off the photovoltaic device 1. The chemical liquid for removing the mask material layer 2 may be sodium hydroxide solution or potassium hydroxide solution.

It should be noted that the viscosity of the mask material may be 2 cP to 30000 cP, and the viscosity is exemplarily 150 cP to 6000 cP. The structure of the photovoltaic device 1 may be at least PERC, TOPCON, IBC, HJT, thin-film solar cell, or stacked solar cell of crystalline-silicon solar cell and thin-film solar cell.

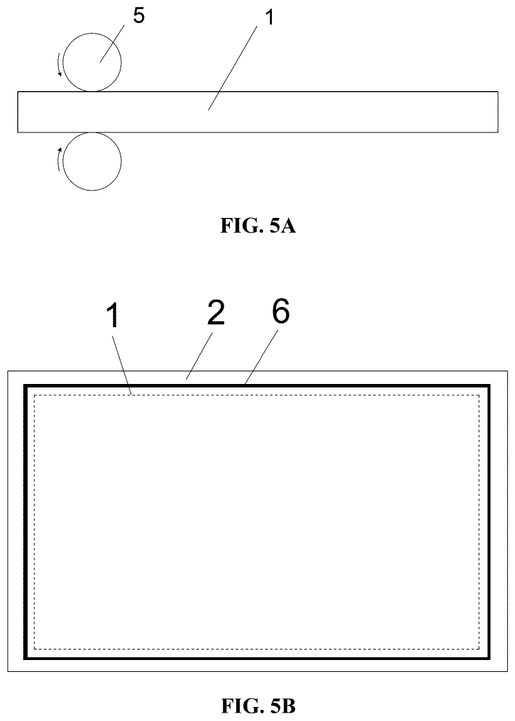

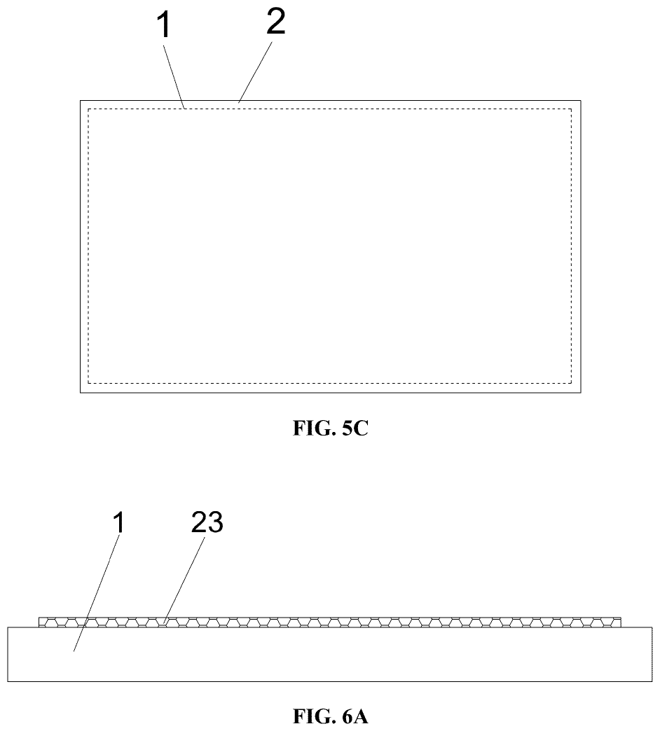

As shown in FIGS. 5A to 5C, in the method provided by another embodiment of the present application, the mask material is simultaneously deposited over the side and the surface of the photovoltaic device 1 by one-step deposition. As shown in FIG. 5A, the mask material is simultaneously coated over the upper surface and the lower surface of the photovoltaic device 1 by roller coating. Two coating rollers 5 are disposed oppositely, abutting against the upper surface and the lower surface of the photovoltaic device 1, respectively. The rotation axes of the two coating rollers 5 are parallel to each other. One of the two coating rollers 5 rotates counterclockwise, and the other rotates clockwise. The lengths of the two coating rollers 5 along their rotation axes are greater than the width of the photovoltaic device 1 so that the width of the mask material layer 2 formed by coating in the direction of the width of the photovoltaic device 1 exceeds the width of the photovoltaic device 1. Before the photovoltaic device 1 enters a gap between the two coating rollers 5 and after the photovoltaic device 1 leaves the gap between the two coating rollers 5, the two coating rollers 5 keep working for a while. In this manner, the length of the mask material layer 2 formed by coating in the direction of the length of the photovoltaic device 1 exceeds the length of the photovoltaic device 1. Thus, the mask material layer 2 can completely cover the surface of the photovoltaic device 1 and extend beyond the edge of the photovoltaic device 1. As shown in FIG. 5B, the mask material layer 2 extending beyond the edge of the photovoltaic device 1 is pressed so that the mask material layer 2 extending from the upper surface of the photovoltaic device 1 and the mask material layer 2 extending from the lower surface of the photovoltaic device 1 can be firmly bonded together. A frame-shaped blade 6 adapted to the shape of the photovoltaic device 1 is used to press the mask material layer 2 extending beyond the edge of the photovoltaic device 1. Meanwhile, the frame-shaped blade 6 cuts off the mask material layer 2 outside the frame-shaped blade 6. In this manner, the side of the mask material layer 2 extending beyond the edge of the photovoltaic device 1 is kept flush, and finally the covering state of the mask material layer 2 shown in FIG. is formed.

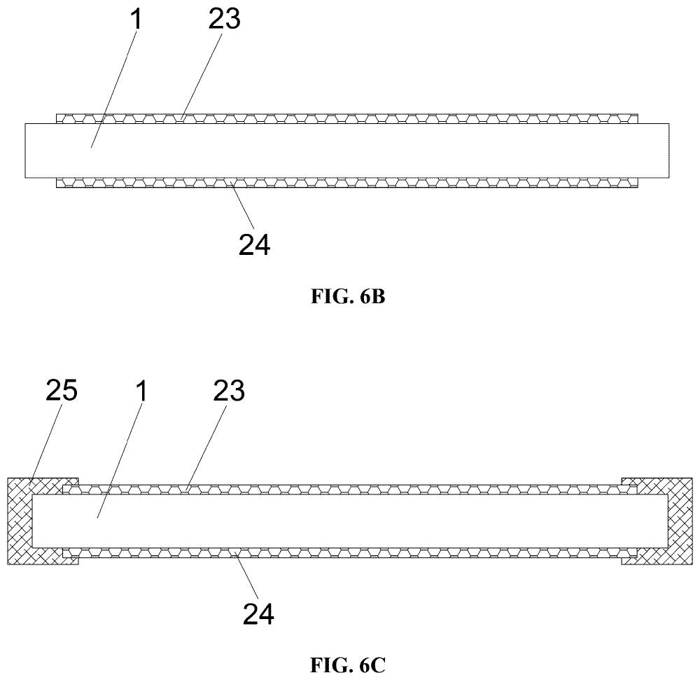

As shown in FIGS. 6A to 6C, in the method provided by another embodiment of the present application, the mask material is deposited on the side and the surface of the photovoltaic device 1 separately. As shown in FIG. 6A, a mask material is deposited on the upper surface of the photovoltaic device 1 to form a first mask material layer 23, and the first mask material layer 23 is dried. As shown in FIG. 6B, a mask material is deposited on the lower surface of the photovoltaic device 1 to form a second mask material layer 24, and the second mask material layer 24 is dried. As shown in FIG. 6C, a mask material is deposited on the side of the photovoltaic device 1 to form a side mask material layer 25, and the side mask material layer 25 is dried. The edge of the side mask material layer 25 overlaps the edge of the first mask material layer 23 on the upper surface of the photovoltaic device 1 to prevent a gap between the side mask material layer 25 and the first mask material layer 23 on the upper surface. The edge of the side mask material layer 25 overlaps the edge of the second mask material layer 24 on the lower surface of the photovoltaic device 1 to prevent a gap between the side mask material layer and the second mask material layer 24 on the lower surface. The first mask material layer 23, the second mask material layer 24, and the side mask material layer 25 are collectively referred to as the mask material layer 2. In this embodiment, after the mask material layer 2 is formed each time, the formed mask material layer 2 is dried to avoid deformation or local shedding.

Optionally, the mask material layer 2 is formed on the upper surface and/or the lower surface by screen printing, and the mask material layer 2 is formed on the side by roller coating.

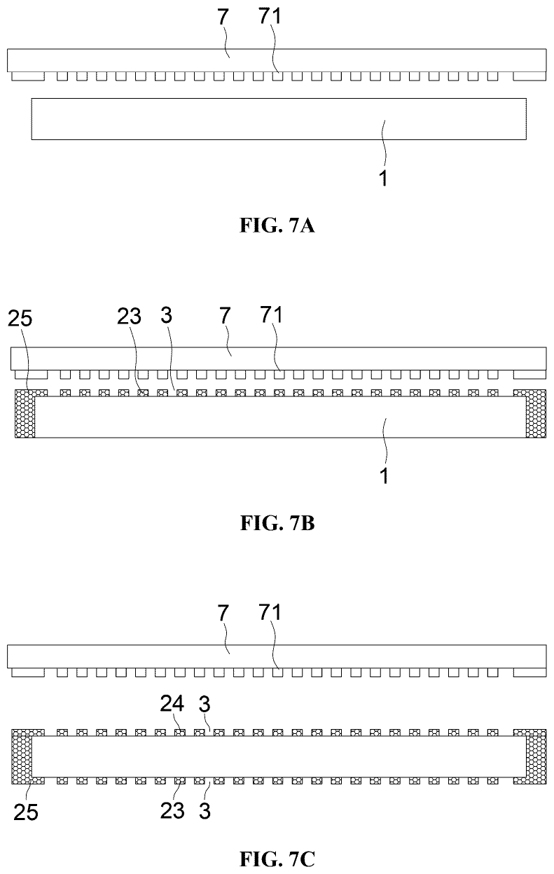

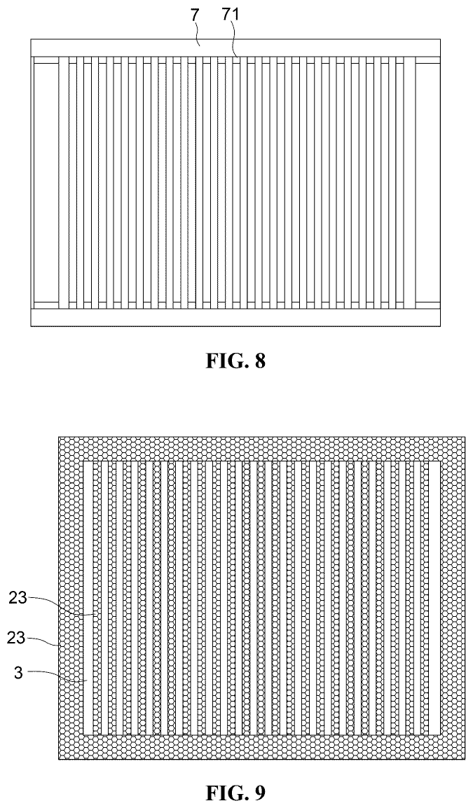

As shown in FIG. 7B, the first mask material layer 23 and a local opening 3 are printed on the upper surface of the photovoltaic device 1, and meanwhile, the side mask material layer 25 is printed on the side of the photovoltaic device 1. Illustratively, as shown in FIG. 9, local openings 3 are multiple rectangular grooves disposed at intervals in the direction of the width (the directions of left and right in FIG. 9), the first mask material layer 23 includes a frame structure disposed around a circle of the edge of the upper surface of the photovoltaic device 1 and multiple rectangular protrusions disposed at intervals in a region surrounded by the frame structure, and a gap between two adjacent rectangular protrusions constitutes a local opening 3. Illustratively, hot wax, with a preset temperature, is used as printing material, and after hot wax being printed over the upper surface and the side of the photovoltaic device 1, the hot wax is cooled by a cooling platform to solidify to form the first mask material layer 23 and the side mask material layer 25. As shown in FIG. 7C, after the photovoltaic device 1 is turned over, a second mask material layer 24 is printed over the lower surface of the photovoltaic device 1. It should be understood that after the photovoltaic device 1 is turned over, the lower surface of the photovoltaic device 1 is disposed above the upper surface of the photovoltaic device 1. Illustratively, hot wax, with a preset temperature, is used as printing material, and after hot wax being printed over the lower surface, the hot wax is cooled by the cooling platform to solidify to form the second mask material layer 24. Illustratively, as shown in FIG. 7A, a printing device 7 includes a printing head 71, and wax is sprayed onto the photovoltaic device 1 via the printing head 71. Illustratively, as shown in FIG. 8, the printing head 71 includes a rectangular vent, and the printing device 7 includes multiple printing heads 71 disposed at equal intervals.

The first mask material layer 23, the local opening 3, and the side mask material layer 25 are formed by one-step printing, which can improve printing efficiency.

Optionally, the second mask material layer 24 and a local opening 3 are printed on the lower surface of the photovoltaic device 1, and meanwhile, the side mask material layer 25 is printed on the side of the photovoltaic device 1. Local openings 3 are formed on both the upper surface and the lower surface of the photovoltaic device 1 so that an electrode 4 can be formed on both the upper surface and the lower surface of the photovoltaic device 1 subsequently. The first mask material layer 23 extends from the upper surface of the photovoltaic device 1 to cover the side of the photovoltaic device 1, and the second mask material layer 24 extends from the lower surface of the photovoltaic device 1 to cover the side of the photovoltaic device 1. The side mask material layer 25 is formed on the side of the photovoltaic device 1 twice successively, which can improve the coating effect of the side and reduce the risk of penetration on the side.

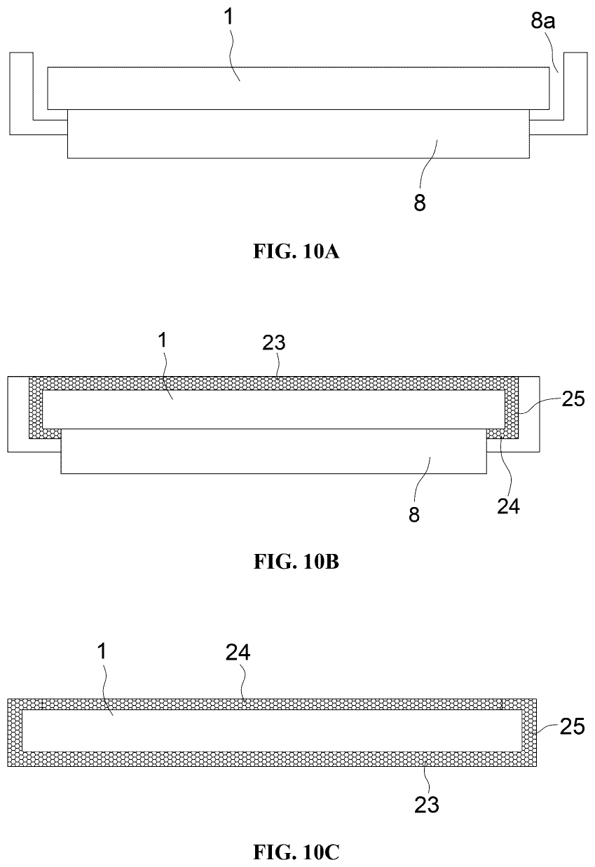

As shown in FIG. 10A, the photovoltaic device 1 is placed on a carrier 8, and a filling gap 8a is formed between the photovoltaic device 1 and an inner sidewall of the carrier 8. The mask material is deposited on the upper surface of the photovoltaic device 1 and the filling gap 8a to form a mask material layer 2 (including the first mask material layer 23, the side mask material layer 25, and part of the second mask material layer 24 on the edge of the lower surface) on the upper surface, the side, and the edge of the lower surface of the photovoltaic device 1. After the deposited mask material layer 2 is dried, the mask material is deposited on the middle of the lower surface of the photovoltaic device 1 to form a second mask material layer 24 connecting the edge of the lower surface. The mask material layer 2 over the upper surface of the photovoltaic device 1 and the mask material layer 2 over the side are manufactured at one step, which can improve manufacturing efficiency.

Optionally, the photovoltaic device 1, after being turned over, is placed on a carrier 8, and a filling gap 8a is formed between the photovoltaic device 1 and an inner sidewall of the carrier 8. The mask material is deposited on the lower surface of the photovoltaic device 1 and the filling gap 8a to form a mask material layer 2 (including the second mask material layer 24, the side mask material layer 25, and part of the first mask material layer 23 on the edge of the upper surface) on the lower surface, the side, and the edge of the upper surface of the photovoltaic device 1. Both the first deposition and the second deposition form a side mask material layer 25 on the side of the photovoltaic device 1, which can improve the coating effect of the side and reduce the risk of penetration on the side.

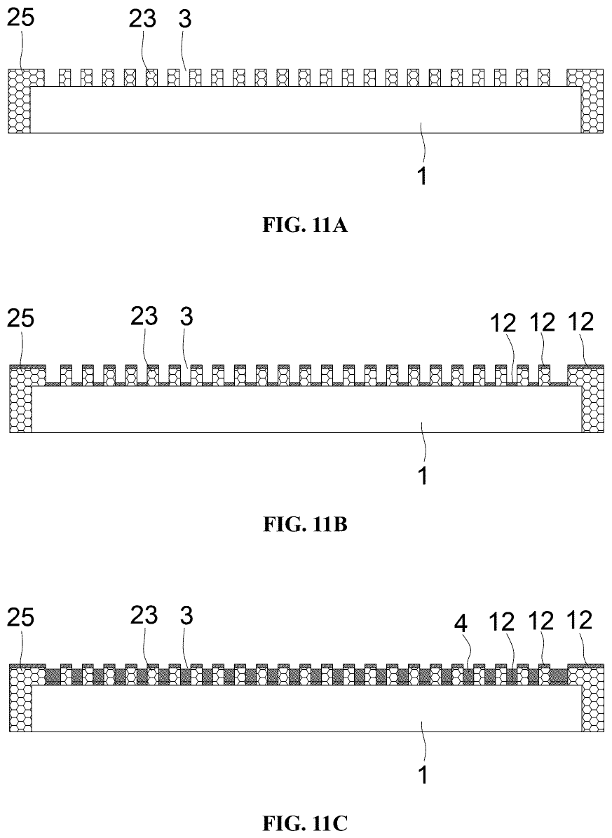

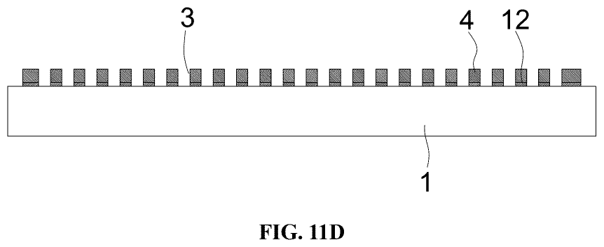

As shown in FIGS. 11A to 11D, another embodiment of the present application provides a method for making an electrode of a photovoltaic cell. The method includes the steps shown below.

A mask material is deposited on the side and at least one surface of a photovoltaic device 1. Illustratively, as shown in FIG. 11A, a mask material is deposited on the entire side and the upper surface of the photovoltaic device 1 to form a continuous mask material layer 2 over the entire side and the upper surface of the photovoltaic device 1; the mask material layer 2 over the upper surface of the photovoltaic device 1 is referred to as a first mask material layer 23; the mask material layer 2 over the side of the photovoltaic device 1 is referred to as a side mask material layer 25. For example, the photovoltaic device 1 is a rectangular sheet with rounded corners, and the side of the photovoltaic device 1 includes four rectangular surfaces and four arcuate surfaces.

The mask material layer 2 over the surface is patterned to form a local opening 3. Illustratively, as shown in FIG. 11A, the first mask material layer 23 on the upper surface is patterned to form local openings 3. The local openings 3 may be formed by the methods in the preceding embodiments, for example, by exposure and development.

The mask material layer 2 over the side is subject to resist treatment and anti-plating treatment. Illustratively, as shown in FIG. 11A, the side mask material layer 25 on the entire side is subject to resist treatment and anti-plating treatment. The resist treatment and anti-plating treatment include using light or heat treatment to cause a photopolymerization reaction or a photocross-linking reaction on the mask material of side mask material layer 25 on the entire side.

A conductive seed layer 12 is formed by sputtering at least at the bottom of the local opening 3, which can reduce the coverage area of the conductive seed layer 12 and reduce the damage to the surface of the photovoltaic device 1 during a sputtering process. Illustratively, as shown in FIG. 11B, a conductive seed layer 12 is formed by sputtering at the first mask material layer 23 and the bottom of the local opening 3. Due to the protection of the first mask material layer 23, the conductive seed layer 12 covers the first mask material layer 23, and the surface of the photovoltaic device 1 covered by the first mask material layer 23 is not damaged in a sputtering process.

Metal is electrochemically deposited in the local opening to form an electrode 4. Illustratively, as shown in FIG. 11C, metal is electrochemically deposited in the local opening 3 on the conductive seed layer 12 of the upper surface of the photovoltaic device 1 to form an electrode 4.

The mask material layer 2 over the surface and the side of the photovoltaic device 1 is removed. Illustratively, as shown in FIG. 11D, the mask material layer 2 over the entire side and the upper surface of the photovoltaic device 1 is removed, and since part of the conductive seed layer 12 is attached to the mask material layer 2 over the upper surface of the photovoltaic device 1, this part of the conductive seed layer 12 may be removed together when the mask material layer 2 is removed.

Alternatively, the mask material is deposited on the entire side, upper surface, and lower surface of the photovoltaic device 1 to form a continuous mask material layer 2 over the entire side, upper surface, and lower surface of the photovoltaic device 1. The mask material layer 2 formed on the upper surface and the lower surface is patterned to form a local opening 3. The side mask material layer 25 on the entire side is subjected to resist and anti-plating treatment. A conductive seed layer 12 is formed by sputtering on the mask material layer 2 and the local opening 3 on the upper surface of the photovoltaic device 1, and a conductive seed layer 12 is formed by sputtering on the mask material layer 2 and a local opening 3 on the lower surface of the photovoltaic device 1. Metal is electrochemically deposited in the local opening 3 on the upper surface of the photovoltaic device 1 to form an electrode 4, and metal is electrochemically deposited in the local opening 3 on the lower surface of the photovoltaic device 1 to form an electrode 4. The mask material layer 2 over the entire side, the upper surface, and the lower surface of the photovoltaic device 1 is removed, and since part of the conductive seed layer 12 is attached to the mask material layer 2 over the upper surface and the lower surface of the photovoltaic device 1, this part of the conductive seed layer 12 may be removed together when the mask material layer 2 is removed.

It should be noted that technical solutions in these embodiments may be combined with any one of the preceding embodiments or a combination of at least two embodiments to form a new embodiment according to technique requirements.

What is claimed is:

1. A method for making an electrode of a photovoltaic cell, comprising:
S1, depositing a mask material over a side and at least one surface of a photovoltaic device to form a mask material layer over the side and the at least one surface, wherein the mask material layer is divided into body part and opening part;
S2, performing a patterning process on the opening part to remove the opening part to form a local opening;
S3, depositing metal in the local opening to form an electrode by using an electrochemical deposition method; and
S4, removing the body part.

2. The method of claim 1, wherein the patterning process in S2 comprises:
in a case where the mask material is a positive resist, using ultraviolet light or laser to expose the opening part such that a photopolymerization reaction, a photocross-linking reaction, or a photodecomposition reaction occurs on the opening part, and using a developer to remove the exposed opening part to form the local opening; or
in a case where the mask material is a negative resist, using ultraviolet light or laser to expose the body part such that a photocross-linking reaction or a photopolymerization reaction occurs on the body part, and using a developer to remove the unexposed opening part to form the local opening.

3. The method of claim 2, further comprising:
performing resist treatment and anti-plating treatment on the body part or the mask material layer over the side before or after using the developer to remove the unexposed opening part to form the local opening.

4. The method of claim 3, wherein the resist treatment and the anti-plating treatment comprise using light treatment or heat treatment to cause the photopolymerization reaction or the photocross-linking reaction on the body part or the mask material layer over the side.

5. The method of claim 3, wherein performing the resist treatment and the anti-plating treatment on the body part or the mask material layer over side comprises:
in a case where the mask material is the positive resist, either performing the resist treatment and the anti-plating treatment on the body part or the mask material layer over the side before using the developer to remove the unexposed opening part to form the local opening, wherein the resist treatment and the anti-plating treatment comprise using heat treatment to cause the photopolymerization reaction or the photocross-linking reaction on the body part or the mask material layer over the side; or performing the resist treatment and the anti-plating treatment on the body part or the mask material layer over the side after using the developer to remove the unexposed opening part form the local opening, wherein the resist treatment and the anti-plating treatment comprise using light treatment or heat treatment to cause the photopolymerization reaction or a photocross-linking reaction on the body part or the mask material layer over the side; or
in a case where the mask material is the negative resist, performing the resist treatment and the anti-plating treatment on the body part or the mask material layer over the side before or after using the developer to remove the unexposed opening part to form the local opening, wherein the resist treatment and the anti-plating treatment comprise using light treatment or heat treatment to cause the photopolymerization reaction or the photocross-linking reaction on the body part or the mask material layer over the side.

6. The method of claim 2, wherein a wavelength range of the ultraviolet light or laser is 300 nm to 450 nm.

7. The method of claim 1, wherein in S1, the mask material is deposited over the side and the at least one surface simultaneously by one-step deposition; or the mask material is deposited over the side and the at least one surface separately.

8. The method of claim 1, wherein the at least one surface comprises an upper surface and a lower surface; and the depositing in S1 comprises:
first deposition, depositing the mask material over the side and the upper surface to form a mask material layer over the side and the upper surface; and
second deposition, depositing the mask material over the side and the lower surface to form a mask material layer over the side and the lower surface,
wherein the mask material layer formed by the first deposition over the side at least partially overlaps the mask material layer formed by the second deposition over the side.

9. The method of claim 1, wherein the electrochemical deposition method in S3 comprises any one or a combination of two or more of screen printing, roller coating, brush coating, slit coating, curtain coating, spray coating, spin coating, dip coating, or inkjet printing.

10. The method of claim 1, wherein the electrochemical deposition method in S3 comprises electroplating deposition and chemical deposition, and the electrode may be a single layer structure or a multi-layer structure, and the material of each layer of the electrode includes any one or an alloy of two or more of nickel, copper, tin, silver, bismuth, or indium.

11. The method of claim 1, wherein the photovoltaic device includes a device body and before S1, the method further comprises:
forming a conductive seed layer over the side and the at least one surface of the device body; and in S1, covering the surface of the conductive seed layer with the mask material layer; or
forming a conductive layer over a surface of the device body; and in S1, covering the surface of the conductive layer and the side of the device body and the conductive layer with the mask material layer.

12. The method of claim 1, wherein the photovoltaic device includes a device body and before S1, the method further comprises:
forming a conductive layer over a surface of the device body; and
forming a conductive seed layer over the side of the device body and the conductive layer,
wherein the conductive seed layer is formed over the surface of the conductive layer.

13. The method of claim 11, wherein the conductive seed layer is a single layer structure or a multi-layer structure, and the material of each layer of the conductive seed layer includes any one or an alloy of two or more of nickel, copper, or tin.

14. The method of claim 11, wherein the conductive layer is a single layer structure or a multi-layer structure, and the material of each layer of the conductive layer includes any one or a mixed material of two or more conductive materials of doped polysilicon, doped amorphous silicon, doped silicon carbide, transparent conductive oxide, or the material of the conductive seed layer.

15. The method of claim 1, wherein a viscosity range of the mask material is 150 cP to 6000 cP.

16. The method of claim 1, wherein the mask material is a wet film photoresist, a dry film photoresist, or a photosensitive ink.

17. The method of claim 1, wherein the mask material comprises a phenolic resin.

18. The method of claim 11, after S4, further comprising:
S5, removing a part of the conductive seed layer except a part of the conductive seed layer occupied by the electrode.

19. The method of claim 1, after S2 and before S3, further comprising:
forming a conductive seed layer only on a surface of the photovoltaic device at the local opening; or
forming a conductive seed layer on a surface of the photovoltaic device at the local opening and on the mask material layer on the at least one surface.
